(19) United States
(12) Patent Application Publication
(10) Pub. No.: US 2026/0130001 A1
(43) Pub. Date: May 7, 2026

(54) IMAGE SENSOR

(71) Applicant: Samsung Electronics Co., Ltd., Suwon-si (KR)

(72) Inventors: Moon Gyu HAN, Suwon-si (KR); Kyung Bae PARK, Suwon-si (KR); Taehyung KIM, Suwon-si (KR); Dae-Yong SON, Suwon-si (KR)

(73) Assignee: Samsung Electronics Co., Ltd., Suwon-si (KR)

(21) Appl. No.: 19/301,442

(22) Filed: Aug. 15, 2025

(30) Foreign Application Priority Data
Nov. 7, 2024 (KR) 10-2024-0157328

(51) Int. Cl. H10F 77/14; H10F 39/00

(52) U.S. Cl. CPC H10F 77/1433; H10F 39/8057; H10F 39/811

(57) ABSTRACT

An image sensor includes first and second electrode layers, a photocharge generating layer between the first and second electrode layers and configured to generate a photocharge based on absorbing incident light, the photocharge generating layer configured to have a first highest occupied molecular orbital (HOMO) level, a hole transport layer between the first electrode layer and the photocharge generating layer and having a second HOMO level different from the first HOMO level by a difference value that is greater than or equal to a first threshold value, and an electron transport layer between the photocharge generating layer and the second electrode layer. The image sensor causes a pixel current based on the photocharge to flow between the second electrode layer and the first electrode layer, based on a first pixel voltage equal to or greater than a second threshold value being applied to the second electrode layer.

### CROSS-REFERENCE TO RELATED APPLICATION

This application claims priority to and the benefit of Korean Patent Application No. 10-2024-0157328, filed in the Korean Intellectual Property Office on Nov. 7, 2024, the entire contents of which are incorporated herein by reference.

### BACKGROUND

### 1. Field

The present inventive concepts relate to image sensors.

### 2. Description of the Related Art

An image sensor is a device that captures a 2D or 3D image of an object. The image sensor creates an image of the object using a photoelectric conversion device that reacts according to intensity of light reflected from the object, for example based on photoelectrically converting incident light into an electrical signal, etc. Recently, with the advancement of complementary metal-oxide semiconductor (CMOS) technology, CMOS image sensors using CMOS are being widely used.

In a CMOS image sensor, when using analog pixels that process output of pixels into analog signals, there is a limit to full well capacity, which is an amount of charge that can be processed within the pixel.

### SUMMARY

Some example embodiments provide image sensors using Pb free quantum dots (QD). Some example embodiments provide driving methods for such image sensors.

Some example embodiments provide image sensors capable of increasing a full well capacity. Some example embodiments provide driving methods for such image sensors.

Some example embodiments provide image sensors capable of improving a shutter efficiency. Some example embodiments provide driving methods for such image sensors.

In some example embodiments of the present inventive concepts, an image sensor may include a first electrode layer, a second electrode layer, a photocharge generating layer between the first electrode layer and the second electrode layer, the photocharge generating layer configured to generate a photocharge based on absorbing incident light, the photocharge generating layer configured to have a first highest occupied molecular orbital (HOMO) level, a hole transport layer between the first electrode layer and the photocharge generating layer, the hole transport layer configured to have a second HOMO level, the second HOMO level different from the first HOMO level by a difference value, the difference value greater than or equal to a first threshold value, and an electron transport layer between the photocharge generating layer and the second electrode layer. The image sensor may be configured to cause a pixel current based on the photocharge to flow between the second electrode layer and the first electrode layer, based on a first pixel voltage applied to the second electrode layer, the first pixel voltage equal to or greater than a second threshold value.

In an image sensor according to some example embodiments, the photocharge generating layer may include a plurality of short-wavelength infrared quantum dots, and the plurality of short-wavelength infrared quantum dots may include an indium arsenide (InAs) material.

In an image sensor according to some example embodiments, the first threshold value may be equal to or greater than 0.2 eV.

In an image sensor according to some example embodiments, the second threshold value may be equal to or greater than 0.5 V.

In an image sensor according to some example embodiments, the image sensor may be configured to cause the difference value to decrease based on the first pixel voltage being applied to the second electrode layer.

In an image sensor according to some example embodiments, the photocharge generating layer may be configured to absorb the incident light to generate a plurality of holes and a plurality of electrons based on the first pixel voltage applied to the second electrode layer, and the image sensor may be configured to cause the plurality of holes to be transferred to the first electrode layer through the hole transport layer and the plurality of electrons to be transferred to the second electrode layer through the electron transport layer.

In an image sensor according to some example embodiments, the image sensor may be configured to cause the difference value to increase based on a second pixel voltage being applied to the second electrode layer, the second pixel voltage smaller than the second threshold value.

According to some example embodiments of the present inventive concepts, an image sensor may include a first electrode layer on a first surface of a semiconductor substrate, a photosensitive layer positioned below the first electrode layer, the photosensitive layer including a plurality of short-wavelength infrared quantum dots, the photosensitive layer configured to generate a photocharge based on absorbing incident light, a second electrode layer positioned at a lower portion of the photosensitive layer, an insulating layer at a lower portion of the semiconductor substrate, the insulating layer configured to include a floating diffusion region on a second surface of the semiconductor substrate, and a first metal layer extending from a lower portion of the second electrode layer to the second surface of the semiconductor substrate, the first metal layer configured to transfer the photocharge to the floating diffusion region.

In an image sensor according to some example embodiments, the plurality of short-wavelength infrared quantum dots may include an indium arsenide (InAs) material.

In an image sensor according to some example embodiments, the image sensor may be configured to cause the photocharge to be accumulated in the floating diffusion region and the first metal layer.

In an image sensor according to some example embodiments, the image sensor may further include a plurality of transistors on the second surface, a plurality of contacts configured to transfer a plurality of control signals to the plurality of transistors, and a second metal layer between the second surface and the second electrode layer, the second metal layer configured to block light incident on the first surface from passing through the semiconductor substrate to reach the second surface.

In an image sensor according to some example embodiments, the floating diffusion region may be spaced apart from the plurality of transistors, and the image sensor may be configured to cause a size of the floating diffusion region to increase in response to accumulation of the photocharge in the floating diffusion region.

In an image sensor according to some example embodiments, the photosensitive layer may include a photocharge generating layer including the plurality of short-wavelength infrared quantum dots, the photocharge generating layer configured to have a first highest occupied molecular orbital (HOMO) level, a hole transport layer between the first electrode layer and the photocharge generating layer, the hole transport layer configured to have a second HOMO level, the second HOMO level different from the first HOMO level by a difference value, the difference value greater than or equal to a first threshold value, and an electron transport layer between the second electrode layer and the photocharge generating layer.

In an image sensor according to some example embodiments, the image sensor may be configured to cause a plurality of holes generated from the photosensitive layer to be transferred to the hole transport layer and a plurality of electrons generated from the photosensitive layer to be transferred to the electron transport layer, based on a first pixel voltage applied to the second electrode layer, the first pixel voltage equal to or greater than a second threshold value.

In an image sensor according to some example embodiments, the first threshold value may be equal to or greater than 0.2 eV.

In an image sensor according to some example embodiments, the second threshold value may be equal to or greater than 0.5 V.

In an image sensor according to some example embodiments, the image sensor may be configured to cause the difference value to increase based on a second pixel voltage being applied to the second electrode layer, the second pixel voltage smaller than a second threshold value.

According to some example embodiments of the present inventive concepts, an image sensor may include a photodetector including a photosensitive layer, the photosensitive layer including a plurality of short-wavelength infrared quantum dots, the plurality of short-wavelength infrared quantum dots including an indium arsenide material, a floating diffusion node connected to a first end of the photodetector, the floating diffusion node configured to accumulate a photocharge generated from the photodetector based on a pixel voltage applied to a pixel of the image sensor being equal to or greater than a first threshold value, a reset transistor connected to the first end of the photodetector and configured to transmit a power supply voltage as a reset signal to the floating diffusion node, a driving transistor including a driving transistor gate, the image sensor configured to cause a voltage of the floating diffusion node to be applied to the driving transistor gate, and a selection transistor connected to a first end of the driving transistor, the selection transistor and configured to transmit the voltage of the floating diffusion node as a pixel signal.

In an image sensor according to some example embodiments, the photodetector may include a first electrode layer, a second electrode layer where the image sensor is configured to cause the pixel voltage to be applied to the second electrode layer, a photocharge generating layer between the first electrode layer and the second electrode layer, the photocharge generating layer configured to generate the photocharge based on absorbing incident light, the photocharge generating layer configured to have a first highest occupied molecular orbital (HOMO) level, a hole transport layer between the first electrode layer and the photocharge generating layer, the hole transport layer configured to have a second HOMO level, the second HOMO level different from the first HOMO level by a difference value, the difference value greater than or equal to a second threshold value, and an electron transport layer between the photocharge generating layer and the second electrode layer.

In an image sensor according to some example embodiments, the image sensor may be configured to cause the difference value to increase based on the pixel voltage being smaller than the first threshold value.

The shutter efficiency of the image sensor may be improved.

### BRIEF DESCRIPTION OF THE DRAWINGS

FIG. 1 illustrates a block diagram of an image sensor, according to some example embodiments.

FIG. 2 illustrates a cross-sectional view of a pixel of FIG. 1, according to some example embodiments.

FIG. 3 illustrates a circuit diagram of a pixel, according to some example embodiments.

FIG. 4 illustrates a cross-sectional view of a portion of a pixel, according to some example embodiments.

FIG. 5 illustrates a timing diagram showing an operation of an image sensor, according to some example embodiments.

FIG. 6 illustrates an image showing a process in which electrons and holes generated from a photosensitive layer according to some example embodiments are transferred to a first electrode layer and a second electrode layer.

FIG. 7 illustrates an image showing a process in which electrons and holes generated from a photosensitive element according to some example embodiments are transferred to a first electrode layer and a second electrode layer.

FIG. 8 illustrates a schematic diagram of a bandgap energy diagram of some components included in a pixel, according to some example embodiments.

FIG. 9 illustrates a graph showing an amount of current generated based on a voltage applied to a second electrode layer, according to some example embodiments.

FIG. 10 illustrates a schematic diagram of a bandgap energy diagram of some components included in a pixel according to a comparative embodiment.

FIG. 11 illustrates a graph showing an amount of current generated based on a voltage applied to a second electrode layer according to the comparative embodiment.

FIG. 12 illustrates a block diagram showing an electronic device according to some example embodiments.

FIG. 13 illustrates a block diagram showing an electronic device according to some example embodiments.

### DETAILED DESCRIPTION

In the following detailed description, only certain example embodiments of the present inventive concepts have been shown and described, simply by way of illustration. As those skilled in the art would realize, the described example embodiments may be modified in various different ways, all without departing from the spirit or scope of the present inventive concepts.

Accordingly, the drawings and description are to be regarded as illustrative in nature and not restrictive. Like reference numerals designate like elements throughout the specification. In a flowchart described with reference to the drawings, an order of operations may be changed, several operations may be merged, some operations may be divided, and specific operations may not be performed.

In addition, expressions written in the singular may be construed in the singular or plural unless an explicit expression such as “one” or “single” is used. Terms including ordinal numbers such as first, second, and the like will be used only to describe various component and are not to be interpreted as limiting these components. These terms may be used for the purpose of distinguishing one constituent element from other constituent elements.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity, and the same or similar constituent elements are indicated by the same reference numeral throughout the specification.

Hereinafter, the terms “lower portion” and “upper portion” are for convenience of description and do not limit the positional relationship.

It will further be understood that when an element is referred to as being “on” another element, it may be above or beneath or adjacent (e.g., horizontally adjacent) to the other element. It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%). Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%).

It will be understood that elements and/or properties thereof may be recited herein as being “identical” to, “the same” or “equal” as other elements and/or properties, and it will be further understood that elements and/or properties thereof recited herein as being “identical” to, “the same” as, or “equal” to other elements and/or properties may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances.

Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or value is referred to as being the same as another element or value, it should be understood that an element or a value is the same as another element or value within a desired manufacturing or operational tolerance range (e.g., ±10%).

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

Hereinafter, the present inventive concepts will be described in more detail through examples. These examples are merely for illustrating the present inventive concepts, and the scope of right protection of the present inventive concepts is not limited by these examples.

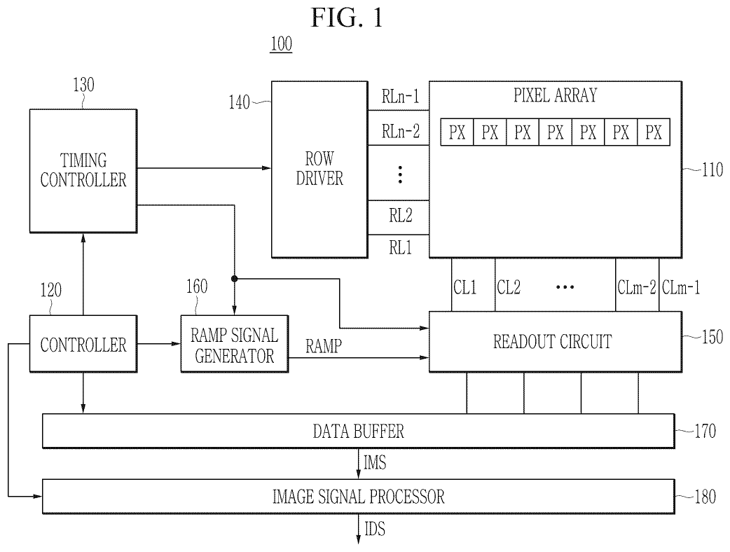

FIG. 1 illustrates a block diagram of an image sensor according to some example embodiments.

As illustrated in FIG. 1, the image sensor 100 according to some example embodiments may include a pixel array 110, a controller 120, a timing controller 130, a row driver 140, a readout circuit 150, a ramp signal generator 160, a data buffer 170, and an image signal processor 180. In some example embodiments, the image signal processor 180 may be positioned outside the image sensor 100.

The image sensor 100 may convert light received from an outside (e.g., incident light that is received at and/or incident on one or more portions of the image sensor 100 from an ambient environment that is external to the image sensor 100) into an electrical signal to generate an image signal IMS. The image signal IMS may be supplied to an image signal processor 180.

The image sensor 100 may be mounted on an electronic device having an image or light sensing function. For example, the image sensor 100 may be mounted on an electronic device such as a camera, a smartphone, a wearable device, an Internet of things (IoT) devices, a home appliance, a tablet personal computer (PC), a personal digital assistant (PDA), a portable multimedia player (PMP), a navigation device, a drone, an advanced driver assistance system (ADAS), etc. The image sensor 100 may also be mounted on an electronic device provided as a part of a vehicle, a furniture, a manufacturing facility, a door, or various measuring devices.

The pixel array 110 may include a plurality of pixels PX, and a plurality of row lines RL1, RL2, . . . , and RL(n−1) and a plurality of column lines CL1, CL2, . . . , and CL(m−1) respectively connected to the pixels PX. The pixels PX may include a photodetector (or photosensitive element) and at least one floating diffusion node FD. The photodetector may detect incident light and generate a photocharge. The photocharge generated by the photodetector may be transferred to the floating diffusion node.

The photodetector may also detect incident light, and may convert the incident light into an electric signal (e.g., a photocharge) according to an amount of light (e.g., an intensity of incident light that is incident on the photodetector), i.e., a plurality of analog pixel signals. A level of the analog pixel signals outputted (transmitted) from the photodetector may be increased as an amount of the photocharge outputted from the photodetector increases. That is, the level of the analog pixel signals output from the photodetector may be increased as an amount (e.g., intensity) of light received into the pixel array 110 increases. In some example embodiments, the photodetector may be a photosensitive layer including a plurality of quantum dots.

The row lines RL1, RL2, . . . and RL(n−1) may extend in a first direction, and may be connected to the pixels PX positioned along the first direction. A plurality of column lines CL1 to CL(m−1) (CL) may extend in a second direction intersecting the first direction, and may be connected to a plurality of pixels PX arranged along the second direction. The column lines CL1, CL2, . . . , CL(m−1) may transmit pixel signals output from the pixels PX to the readout circuit 150. As used herein, “n” and “m” may each independently be any positive integer.

The controller 120 may generally control each of the components 110, 130, 140, 150, 160, 170, and 180 included in the image sensor 100. The controller 120 may control operation timing of each component 110, 130, 140, 150, 160, 170, and 180 using control signals.

In some example embodiments, the controller 120 may control the ramp signal generator 160 to adjust a reference signal RAMP generated by the ramp signal generator 160. In some example embodiments, the controller 120 may control the timing controller 130 to adjust a magnitude (level) of a pixel voltage applied to each of the pixels PX. In some example embodiments, the controller 120 may control the timing controller 130 to adjust operation timings of elements in the pixel array 110 through the row driver 140.

The timing controller 130 may generate a signal that serves as a reference for operation timings of components of the image sensor 100. The timing controller 130 may control timings of the row driver 140, the readout circuit 150, and the ramp signal generator 160. The timing controller 130 may provide (e.g., transmit) a control signal that controls the timings of the row driver 140, the readout circuit 150, and the ramp signal generator 160.

The timing controller 130 may control timings of elements within a pixel PX during a reset period, an integration period, and a readout period. The reset section may be a period in which charges accumulated in floating diffusion nodes within the pixel PX are reset. An integration region may be a region where the photodetector may be exposed to light to generate photocharges and the generated photocharges may be transferred to floating diffusion nodes. The readout period may be a period during which voltages of the floating diffusion nodes is transferred to the readout circuit 150.

The row driver 140 may generate a control signal for driving the pixel array 110 in response to a control signal of the timing controller 130, and control signals may be supplied to the pixels PX of the pixel array 110 through the row lines RL1, RL2, and RL(n−1). In some example embodiments, the row driver 140 may control the pixels PX to sense light incident in a row line unit. The row line unit may include at least one row line RL1, RL2, . . . , and RL(n−1).

The readout circuit 150 may receive pixel signals output from the pixels PX from the column lines CL1, CL2, . . . , and CL(m−1). In response to the control signal from the timing controller 130, the readout circuit 150 may convert pixel signals (or electric signals) from the pixels PX connected to the row line RL1, RL2, . . . , and RL(n−1) selected from among the pixels PX into values of the pixels PX representing an amount (e.g., intensity) of light (e.g., incident light that is incident on the pixels PX).

The ramp signal generator 160 may generate the reference signal RAMP to transmit it to the readout circuit 150. The ramp signal generator 160 may include a current source, a resistor, and a capacitor. The ramp signal generator 160 may generate a plurality of ramp signals that fall or rise with a slope determined according to a current magnitude of a variable current source or a resistance value of a variable resistor by adjusting a lamp voltage, which is a voltage applied to lamp resistance, adjusting the current magnitude of the variable current source or the resistance value of the variable resistor.

The data buffer 170 may store pixel values of the pixels PX connected to a selected column line CL1, CL2, . . . , and CL(m−1) transmitted from the readout circuit 150. The data buffer 170 may output a pixel (PX) value stored in response to an enable signal from the controller 120 to the image signal processor 180 as an image signal IMS.

The image signal processor 180 may perform image signal processing on the image signal IMS received from the data buffer 170. For example, the image signal processor 180 may receive a plurality of image signals IMS from the data buffer 170, and may generate image data IDS by synthesizing the received image signals IMS.

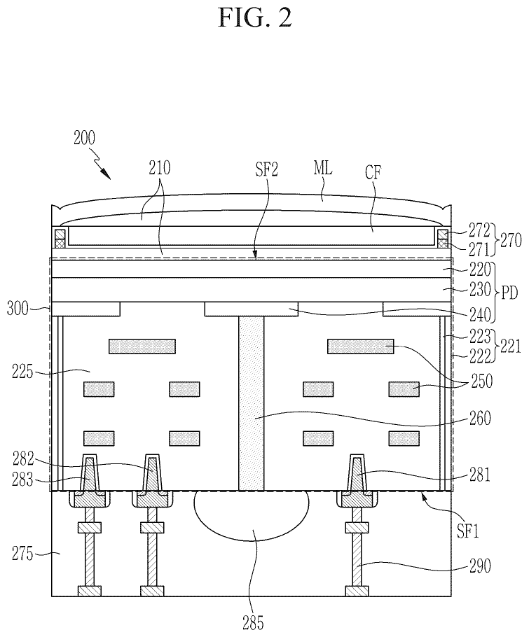

FIG. 2 illustrates a cross-sectional view of a pixel of FIG. 1, according to some example embodiments.

Referring to FIG. 2, the pixel 200 may include a micro lens ML, a color filter layer CF, a surface insulating layer 210, and a color filter grid 270.

The micro lens ML may have a convex shape, and may have a particular (or, alternatively, predetermined) radius of curvature. Micro lenses ML may be arranged to correspond to each pixel region.

The color filter layer CF may be disposed below the micro lens ML. The color filter layer CF may be disposed on the surface insulating layer 210. The color filter layer CF may be positioned to correspond to each unit pixel. The color filter layers CF may be arranged two-dimensionally in a plan view. The color filter layer CF may pass reflected light incident through the micro lens ML, and may allow only light of the required wavelength to enter. The color filter layer CF may be referred to as a color filter array. In some example embodiments, the color filter layer CF may be omitted to acquire only color images, infrared images, or depth images.

The surface insulating layer 210 may include a plurality of surface insulating layer portions 210. The surface insulating layer 210 (e.g., a first surface insulating layer portion) may be positioned between the micro lens ML and the color filter layer CF. The surface insulating layer 210 (e.g., a second surface insulating layer portion) may be positioned between the color filter layer CF and a semiconductor substrate 300. The Surface insulating layer 210 may include a silicon oxide (SiO₂). The color filter layer CF and the semiconductor substrate 300 may be electrically insulated from the surface insulating layer 210.

The color filter grid 270 may be arranged in a mesh shape between the surface insulating layers 210. The color filter grid 270 may define a region where the color filter layer CF is disposed. The color filter grid 270 may be formed on the surface insulating layer 210. The color filter grid 270 may include a metal pattern 271 and a low refractive index pattern 272. The metal pattern 271 and the low refractive index pattern 272 may be sequentially stacked on the surface insulating layer 210.

The pixel 200 may include the semiconductor substrate 300, a plurality of transistors 281, 282, and 283, a plurality of contacts 290, a floating diffusion region 285, and an insulating layer 275.

The semiconductor substrate 300 may be bulk silicon or silicon-on-insulator (SOI). The semiconductor substrate 300 may be a silicon substrate. The semiconductor substrate 300 may include silicon germanium, indium antimonide, lead telluride, indium arsenide, indium phosphide, gallium arsenide, or gallium antimonide.

The semiconductor substrate 300 may include a first surface SF1 and a second surface SF2 that are opposite to each other. The first surface SF1 may be referred to as a front side or lower surface of the semiconductor substrate 300, and the second surface SF2 may be referred to as a back side or upper surface of the semiconductor substrate 300. The surface insulating layer 210 may be stacked on the second surface SF2. Light (e.g., incident light) may be incident on the second surface SF2 of the semiconductor substrate 300 (e.g., incident on the second surface SF2 through the micro lens ML, color filter CF, and surface insulating layer(s) 210).

The semiconductor substrate 300 may include a first electrode layer 220, a photosensitive layer 230, a second electrode layer 240, a first metal layer 250, a second metal layer 260, an isolation pattern 221, and an insulating layer 225. The first electrode layer 220, the photosensitive layer 230, and the second electrode layer 240 may collectively define a photodetector PD. The second electrode layer 240 may include a second electrode layer 240 that transfers is configured to transfer photocharges to a floating diffusion region. This will be described in detail below.

The first electrode layer 220 may be disposed on an upper surface of the photosensitive layer 230. In some example embodiments, the first electrode layer 220 may include an indium tin oxide (ITO). In some example embodiments, the first electrode layer 220 may serve as an anode electrode of the photosensitive layer 230. The first electrode layer 220 may receive light incident on an upper surface of the first electrode layer 220.

The second electrode layer 240 may include aluminum (Al), tin (Tin), magnesium (Mg), and calcium (Ca). In some example embodiments, the second electrode layer 240 may serve as a cathode electrode of the photosensitive layer 230. Light may pass through the first electrode layer 220 and the photosensitive layer 230 to be incident on the upper surface of the second electrode layer 240.

The photosensitive layer 230 may be positioned between the first electrode layer 220 and the second electrode layer 240. The photosensitive layer 230 may generate at least one photocharge through absorption of light. For example, the photosensitive layer 230 may be configured to generate a photocharge based on absorbing incident light. For example, the photosensitive layer 230 may generate at least one electron and at least one hole based on absorbing light (e.g., incident light).

In some example embodiments, the photosensitive layer 230 may include a plurality of quantum dots. The quantum dots may absorb light (e.g., incident light) of a specific wavelength depending on a size of each of the quantum dots. Each of the quantum dots may generate multiple holes and multiple electrons based on absorbing light of a corresponding specific wavelength.

The quantum dots may have tunable band gaps via quantum size effects. In some example embodiments, the quantum dots may be used as light-sensitive materials in light emitting elements, solar cells, optical sensors, and the like. The quantum dots may detect light in ultraviolet, visible, and infrared ranges. The quantum dots may include short wave infrared (SWIR) quantum dots, also referred to herein interchangeably as short-wavelength infrared quantum dots. Red quantum dots and short-wavelength infrared quantum dots may have relatively high light absorption rates for light in an infrared range. In some example embodiments, the quantum dots may include indium arsenide (InAs) materials (e.g., an InAs material) and/or indium antimonide (InSb) materials (e.g., an InSb material). Quantum dots including indium arsenide (InAs) and indium antimonide (InSb) may reduce a possibility of environmental pollution caused by heavy metals such as lead (Pb).

The first metal layer 250, the second metal layer 260, and the insulating layer 225 may be disposed under the second electrode layer 240. The first metal layer 250 may be positioned between the first surface SF1 and the second electrode layer 240. The first metal layer 250 (also referred to in some example embodiments as a second metal layer) may prevent light that is incident on the second surface SF2 from passing through the insulating layer 225 and entering (reaching) the first surface SF1, or may reduce or minimize such passing and entering.

The second metal layer 260 (also referred to in some example embodiments as a first metal layer) may serve as a path through which photocharges generated in the photosensitive layer 230, e.g., multiple electrons and/or multiple holes, are transferred to the floating diffusion region 285. For example, the second metal layer 260 may transfer photocharges generated in the photosensitive layer 230 (also referred to as photocharges generated at the photosensitive layer 230) to the floating diffusion region 285. As described below, the floating diffusion region 285 may accumulate photocharges transferred through the second metal layer 260. Accordingly, the pixel 200, and thus the image sensor 100, may be configured to cause a photocharge that is generated by the photosensitive layer 230 to be accumulated in the floating diffusion region 285 and the second metal layer 260. The second metal layer 260 may be disposed between the second electrode layer 240 and the first surface SF1 of the semiconductor substrate 300. The second metal layer 260 may be in contact with the second electrode layer 240. The second metal layer 260 may be in contact with the first surface SF1 of the semiconductor substrate 300.

The semiconductor substrate 300 may include an insulating layer 225. The insulating layer 225 may prevent a plurality of holes or a plurality of electrons transferred to the floating diffusion region 285 through the second metal layer 260 from leaking from the second metal layer 260, or may reduce or minimize such leakage. In some example embodiments, the insulating layer 225 may include a silicon oxide film (SIO₂).

The isolation pattern 221 may be disposed on an outer surface of the semiconductor substrate 300. The isolation pattern 221 may be, e.g., an insulating material made of an oxide, a nitride, an oxynitride or any combination thereof. The isolation pattern 221 may be formed to include a conductive material layer and a cover insulating layer surrounding the conductive material layer. The conductive material layer may include polysilicon, a metal, or a metal nitride or an oxide such as SiO₂. The cover insulating layer may include an oxide, a nitride, an oxynitride or any combination thereof.

The isolation pattern 221 may define a plurality of unit pixels. The unit pixels may be arranged two-dimensionally in a plan view. The isolation pattern 221 may be formed in a grid shape in a plan view to separate the unit pixels from each other. The isolation pattern 221 may be formed by filling an insulating material in a deep trench formed by patterning the semiconductor substrate 300.

The isolation pattern 221 may include an insulating spacer layer 222 and a conductive filling pattern 223. The insulating spacer layer 222 may extend conformally along a side surface of the trench within the semiconductor substrate 300. The conductive filling pattern 223 may be formed on the insulating spacer layer 222 to fill a portion of the trench within the semiconductor substrate 300. The isolation pattern 221 may be a frontside deep trench isolation (FDTI) pattern.

Meanwhile, in FIG. 2, a frontside deep trench isolation (FDTI) pattern is illustrated in which the isolation pattern 221 extends from the first surface SF1 of the semiconductor substrate 300 to the second electrode layer 240 through the semiconductor substrate 300, but the present inventive concepts are not limited thereto, and the isolation pattern 221 may be a backside deep trench isolation (BDTI) pattern.

The transistors 281, 282, and 283 (also referred to herein as a plurality of transistors) may be positioned on the first surface SF1. The transistors 281, 282, and 283 may include a reset transistor, a driving transistor, and a selection transistor. The transistors 281, 282, and 283 may be connected to the respective contacts 290. The transistors 281, 282, and 283 may receive control signals. The contacts 290 (also referred to herein as a plurality of contacts) may be configured to transfer a plurality of control signals to the plurality of transistors 281, 282, and 283.

The floating diffusion region 285 may be positioned below the first surface SF1, and may be in contact with the second metal layer 260. The floating diffusion region 285 may be positioned spaced apart from each of the transistors 281, 282, and 283. In the floating diffusion region 285, photocharges generated in the photosensitive layer 230, for example, electrons or holes, may be accumulated.

The image sensor 100 (e.g., the pixel 200) may be configured to cause a plurality of electrons or holes accumulated in the floating diffusion node FD to be transferred to the second electrode layer 240 through the second metal layer 260. A voltage of the floating diffusion node FD may be equal or substantially equal to a pixel voltage, which is a voltage input to the second electrode layer 240. The second electrode layer 240 may receive the pixel voltage through the second metal layer 260.

The insulating layer 275 may be disposed on a lower portion of the first surface SF1. The insulating layer 275 may prevent electrons or holes accumulated in the floating diffusion region 285 from leaking out, or reduce or minimize such leakage. The insulating layer 275 may include a silicon oxide film (SI02).

A shutter efficiency of the image sensor 100 may be proportional to an amount of photocharge that the photosensitive layer 230 may generate and inversely proportional to a noise of a storage diode. According to some example embodiments, the photodetector may be positioned on top of the insulating layer 275, so the insulating layer 225 may not include a region (e.g., may not include any region) where the photodetector is positioned. The floating diffusion region 285 may be extended and/or electrically connected (e.g., via the second metal layer 260) to the region where the existing photodetector PD is positioned, a characteristic of a full well capacity (FWC) of the image sensor may be improved, and thus the operating performance of the image sensor 100 may be improved.

According to some example embodiments, the pixel 200 may not include a storage diode (e.g., may not include any storage diode). A size of the floating diffusion region 285 may be expanded by replacing the storage diode. For example, the image sensor 100 may be configured to cause a size of the floating diffusion region 285 to increase in response to accumulation of a photocharge generated by the photosensitive layer 230 in the floating diffusion region 285 (where the photocharge is transferred to the floating diffusion region 285 through the second electrode layer 240 and the second metal layer 260). Photocharges may be interchangeably referred to herein in singular and plurality form. As photocharges accumulate in the floating diffusion region 285, the floating diffusion region 285 may extend to a region where the existing storage diode is positioned. Accordingly, the full well capacity characteristic of the image sensor 100 may be improved based on omitting the storage diode (e.g., not including any storage diodes in the insulating layer 275) and thus configuring the image sensor 100 to enable the floating diffusion region 285 to extend further due to photocharge accumulation based on the absence of any storage diodes. In addition, photocharges may be read directly from the floating diffusion region 285 without a storage diode, so noise generated by the storage diode may be eliminated, thereby improving the image generation functionality of the image sensor 100. The noise generated by the storage diode may be reduced, and the full well capacity characteristic of the image sensor 100 may be improved, so the shutter efficiency of the image sensor 100 may be improved and thus the functionality of the image sensor 100 may be improved.

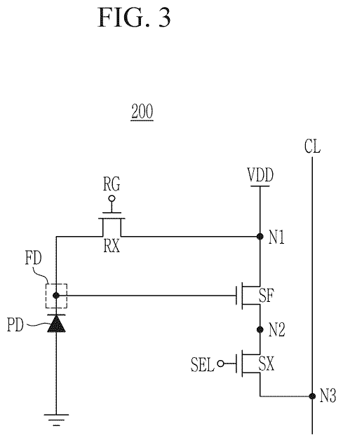

FIG. 3 illustrates a circuit diagram of a pixel according to some example embodiments.

The pixel PX (in FIG. 1) may include a photodetector PD, a reset transistor RX, a driving transistor SF, and a selection transistor SX. A first end of the photodetector PD may be grounded to ground GND. A second end of the photodetector PD may be connected to the floating diffusion node FD. The floating diffusion node FD may accumulate multiple electrons or multiple holes and/or a photocharge generated from the photodetector PD. A plurality of electrons or holes accumulated in the floating diffusion node FD may be transferred to the second electrode layer 240 through the second metal layer 260. A voltage of the floating diffusion node FD may be equal or substantially equal to a pixel voltage, which is a voltage input to the second electrode layer 240.

A first end of the reset transistor RX may be connected to the floating diffusion node FD and thus may be connected to the second end of the photodetector PD via the floating diffusion node FD. The first and second ends of the photodetector PD may be alternatively referred to interchangeably as second and first ends, respectively, of the photodetector PD, for example such that the floating diffusion node FD may be referred to as being connected to a first end of the photodetector PD, and the reset transistor RX may be connected to the first end of the photodetector PD. A second end of the reset transistor RX may receive a power supply voltage VDD from a first node N1. The first node N1 may be connected to a power supply voltage line that supplies the power supply voltage VDD.

The reset transistor RX may be controlled by a reset control signal RG. When the reset transistor RX is turned on, the reset transistor RX may transmit a power supply voltage as a reset signal to the floating diffusion node FD, and the floating diffusion node FD may be reset to the power supply voltage VDD. The second electrode layer 240 may be reset to the power supply voltage VDD. In some example embodiments, when the power supply voltage VDD is a positive voltage, the pixel voltage may increase. When the reset transistor RX is turned on, electrons may be transferred from the floating diffusion node FD to the power supply voltage line through the first node N1. In this case, multiple electrons or multiple holes accumulated in the floating diffusion node FD may be transferred to the power supply voltage line through the second metal layer 260 and the second electrode layer 240.

When the reset transistor RX is turned off, the power supply voltage VDD may not be transferred to the floating diffusion node FD. The floating diffusion node FD and the pixel voltage may not be reset to the power supply voltage VDD. The floating diffusion node FD may accumulate multiple electrons or multiple holes generated from the photodetector PD. The second electrode layer 240 may be connected to the floating diffusion node FD through the second metal layer 260. Accordingly, multiple electrons or holes may be accumulated in the second electrode layer 240 through the second metal layer 260. Accordingly, the voltage of the second electrode layer 240 may be reduced.

A gate of the driving transistor SF may be connected to the floating diffusion node FD. A first end of the driving transistor SF may be connected to the selection transistor SX through a second node N2. A second end of the driving transistor SF may be connected to the first node N1. The second end of the driving transistor SF may receive the power supply voltage VDD through the first node N1. The driving transistor SF may operate as a source-follower amplifier with respect to the voltage of the floating diffusion node FD. The image sensor 100 may be configured to cause a voltage of the floating diffusion node FD to be applied to the driving transistor SF gate. The driving transistor SF may output (transmit) the voltage of the floating diffusion node FD as a pixel signal through the selection transistor SX, such that the selection transistor SX may be configured to transmit the voltage of the floating diffusion node FD as a pixel signal.

The selection transistor SX may be connected to a first end of the driving transistor SF and one of the column lines CL1, CL2, . . . , and CL(m−1), and may be controlled by the selection control signal SEL. When the selection transistor SX is turned on, the voltage of the floating diffusion node FD output from the driving transistor SF may be output to the readout circuit 150 (in FIG. 1) through any one of the column lines CL1, CL2, . . . , and CL(m−1).

For example, when the first selection transistor SX turned on in a readout operation, a pixel signal including a reset signal corresponding to a reset operation or an image signal corresponding to a charge accumulation operation may be outputted through the column lines CL1, CL2, . . . , and CL(m−1).

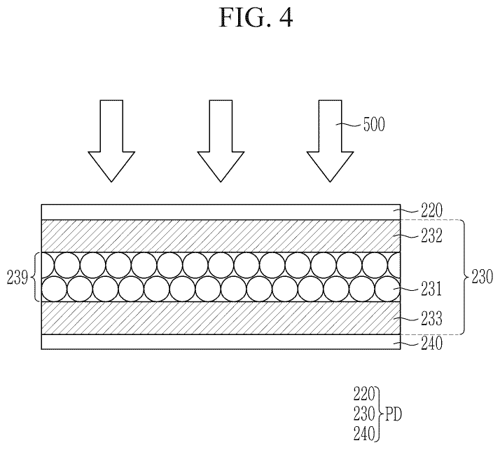

FIG. 4 illustrates a perspective view of a portion of a pixel according to some example embodiments.

Referring to FIG. 4, the pixel PX (in FIG. 1), for example the photodetector PD, may include a first electrode layer 220, a second electrode layer 240, and a photosensitive layer 230 positioned therebetween.

The first electrode layer 220 may be formed of a metal or a transparent metal oxide. The first electrode layer 220 may be formed of an indium tin oxide (ITO). The first electrode layer 220 may serve as an anode electrode. Light 500 (also referred to herein as incident light) may be incident on the first electrode layer 220 from an exterior of the photodetector PD. That is, a direction of incidence of light 500 may be towards an upper surface of the photosensitive layer 230 through the first electrode layer 220.

The second electrode layer 240 may be positioned below the first electrode layer 220. The second electrode layer 240 may be formed of a metallic material. The second electrode layer 240 may include aluminum (Al), tin (Tin), magnesium (Mg), and calcium (Ca). The second electrode layer 240 may serve as a cathode electrode.

The photosensitive layer 230 may include a photocharge generating layer 239, a hole transport layer (HTL) 232, and an electron transport layer (ETL) 233. The photocharge generating layer 239 may be positioned between the first electrode layer 220 and the second electrode layer 240. The photocharge generating layer 239 may be formed over a wide region through a solution process, and may have a bandgap that can be adjusted through the quantum size effect, so it may be used as a light-sensitive material in light emitting elements, solar cells, and optical sensors. The photocharge generating layer 239 may include an indium arsenide (InAs) or indium antimonide (InSb) material.

The photocharge generating layer 239 may be configured to generate a photocharge based on absorbing incident light (e.g., light 500). Because the pixel PX includes the photocharge generating layer 239, it may detect light in ultraviolet, visible, and/or infrared regions. The photocharge generating layer 239 may include at least one of a red quantum dot and a short wave infrared (SWIR) quantum dot 231. For example, the photocharge generating layer 239 may include a plurality of SWIR quantum dots 231, for example SWIR quantum dots 231 that include an InAs material. The red quantum dot and the short-wave infrared quantum dot 231 may have high light absorption rates for light in visible and ultraviolet ranges. The short-wave infrared quantum dot 231 may receive light in a corresponding infrared range to generate holes and electrons.

The hole transport layer 232 may be positioned below the first electrode layer 220. The hole transport layer 232 may be positioned between the first electrode layer 220 and the photocharge generating layer 239. The hole transport layer 232 may be formed of a P-type oxide semiconductor material. The hole transport layer 232 may include Cu₂SnS₃—Ga₂O₃, molybdenum oxide (MoOₓ), zinc oxide (ZnO) doped molybdenum oxide (MoOₓ), copper iodide (CuI), Molybdenum Disulfide (MoS₂), copper oxide (CuO), 2,2′,7,7′-Tetrakis[N,N-di(4-methoxyphenyl)amino]-9,9′-spirobifluorene (Spiro-MeOTAD), and Poly[(9,9-dioctylfluorenyl-2,7-diyl)-co-(4,4′-(N-(4-sec-butylphenyl)diphenylamine)](TFB). Cu₂SnS₃—Ga₂O₃ may have high hall mobility and may have a high optical bandgap. The hole mobility of Cu₂SnS₃—Ga₂O₃ may be about 36.22 cm²/Vs, and the optical bandgap of Cu₂SnS₃—Ga₂O₃ may be about 3.8 eV. The hole transport layer 232 may be used as an electron blocking layer.

The electron transport layer 233 may be positioned below the photocharge generating layer 239. The electron transport layer 233 may be positioned between the second electrode layer 240 and the photocharge generating layer 239. The electron transport layer 233 may be made of a N-type oxide semiconductor material. The electron transport layer (233) may include lithium-doped zinc oxide (LZO), zinc oxide nanoparticles (ZnO nanoparticles), titanium dioxide (TiO₂), tin dioxide (SnO₂), lithium (Li), magnesium-zinc oxide (ZnMgO), and aluminum-doped zinc oxide (AZO). The electron transport layer 233 may be used as a hole blocking layer.

In some example embodiments, the first electrode layer 220, the hole transport layer 232, the photocharge generating layer 239, the electron transport layer 233, and the second electrode layer 240 may be formed of inorganic materials. The materials that make up the pixel PX may be made of inorganic ones, thereby improving stability of the device compared to cases where organic materials are included.

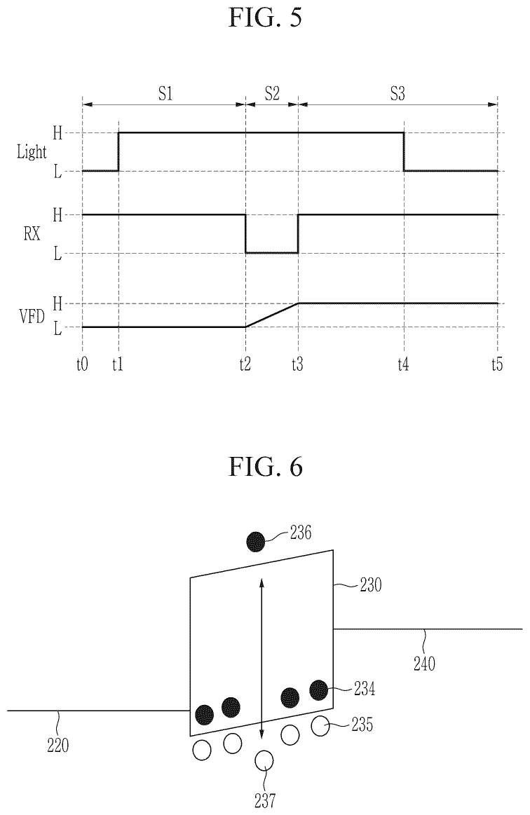

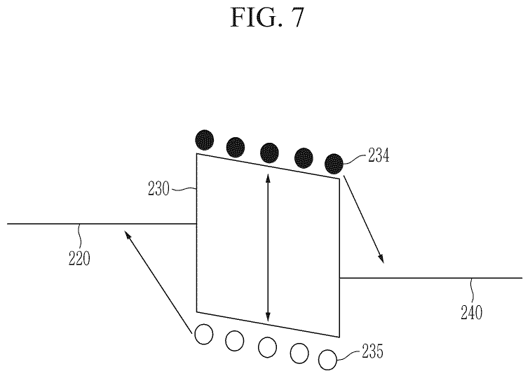

FIG. 5 illustrates a timing diagram showing an operation of an image sensor according to some example embodiments. FIG. 6 illustrates an image showing a process in which electrons and holes generated from a photosensitive layer according to some example embodiments are transferred to a first electrode layer and a second electrode layer. FIG. 7 illustrates an image showing a process in which electrons and holes generated from a photosensitive element according to some example embodiments are transferred to a first electrode layer and a second electrode layer.

Referring to FIGS. 4 and 5, a period t2 to t3 may be an activation period (S2), which is a period in which a pixel current flows due to multiple electrons or multiple holes generated in the photosensitive layer 230. A period t0 to t2 and a period t3 to t5 may be inactivation periods S1 and S3 in which pixel current does not flow because electrons or holes are not sufficiently generated in the photosensitive layer 230.

In FIG. 5, a case where light (e.g., light 500) is incident on the image sensor 100 (e.g., incident on the photodetector PD) is depicted as a high level H, and a case where light 500 is not incident is depicted as a low level L. During a period t0 to t1 and a period t4 to t5, light may not be incident on the photodetector PD. During a period t1 to t4, light may be incident on the first electrode layer 220. In FIG. 5, a period during which light is incident on the first electrode layer 220 is depicted as a high level H, and a period during which light is not incident on the first electrode layer 220 is depicted as a low level L.

During some of the period from t0 to t2, the reset transistor RX (in FIG. 3) may be turned on. A plurality of electrons or holes accumulated in the floating diffusion node FD (in FIG. 3) may be transferred to the power supply voltage line through the second metal layer 260 (in FIG. 2), the second electrode layer 240 (in FIG. 2), and the reset transistor 282 (in FIG. 2).

Referring to FIGS. 5 and 6, during the deactivation period S1, the power supply voltage VDD (in FIG. 3) may be transmitted to the second electrode layer 240 through the reset transistor RX (in FIG. 3), the floating diffusion region 285, and the second metal layer 260. That is, an energy level of the second electrode layer 240 may be set based on the power supply voltage VDD. Accordingly, the energy level of the second electrode layer 240 may be higher than that of the first electrode layer 220.

During the deactivation section S1, multiple electrons 234 and multiple holes 235 of the photosensitive layer 230 may be combined with each other. The electrons 234 may have a negative charge and the holes 235 may have a positive charge, so the electrons 234 and the holes 235 may be combined with each other. However, some of the electrons 234 may be released from the photosensitive layer 230, becoming free electrons 236. Some of the holes 235 may be released from the photosensitive layer 230, becoming free holes 237. The free electrons 236 may be transferred to the first electrode layer 220. The free holes 237 may be transferred to the second electrode layer 240. However, numbers of free electrons 236 and free holes 237 may be significantly small, so pixel current may not flow from the first electrode layer 220 to the second electrode layer 240.

During the period t2 to t3, the reset transistor RX may be turned off. When the reset transistor RX is turned off, multiple electrons or multiple holes may be generated as one or more photocharges in the photodetector PD (in FIG. 3). The electrons or holes may be accumulated (as one or more photocharges so accumulated) in the floating diffusion node FD through the second electrode layer 240 and the second metal layer 260.

Referring to FIGS. 5 and 6, during the activation period S2, the photosensitive layer 230 may absorb light to generate the electrons 234 and the holes 235. The electrons 234 may be released from the photosensitive layer 230, becoming free electrons 236. The holes 235 may be released from the photosensitive layer 230, becoming free holes 237.

The electrons 234 may be transferred from the photosensitive layer 230 to the second electrode layer 240. The holes 235 may be transferred from the photosensitive layer 230 to the first electrode layer 220. Accordingly, a pixel current may flow between the second electrode layer 240 and the first electrode layer 220, for example from the second electrode layer 240 to the first electrode layer 220.

During the activation period S2, the electrons 234 generated in the photosensitive layer 230 can be transferred to the second electrode layer 240. During the activation period S2, the reset transistor RX (in FIG. 3) may be turned off, so the power supply voltage VDD (in FIG. 3) may not be transmitted to the second electrode layer 240. Accordingly, the energy level of the second electrode layer 240 may be lower than that of the first electrode layer 220.

During the period t0 to t2, the photosensitive layer 230 may not generate multiple electrons or multiple holes (e.g., may not generate any photocharges). The photosensitive layer 230 may not transfer multiple electrons or multiple holes to the floating diffusion node FD (in FIG. 3). During the period t2 to t3, the photosensitive layer 230 may generate multiple electrons or multiple holes (e.g., may generate one or more photocharges). The photosensitive layer 230 may transfer multiple electrons or multiple holes (e.g., transfer the one or more photocharges) to the floating diffusion node FD.

When the photosensitive layer 230 transfers the holes to the floating diffusion node FD, a floating diffusion voltage VFD of the floating diffusion node FD may be at a low level L during the period t0 to t2, and the floating diffusion voltage VFD of the floating diffusion node may transition from a low level L to a high level H during the period t2 to t3.

When the photosensitive layer 230 transfers the electrons to the floating diffusion node FD, a floating diffusion voltage VFD of the floating diffusion node FD may be at a high level H during the period t0 to t2, and the floating diffusion voltage VFD of the floating diffusion node FD may transition from a high level H to a low level L during the period t2 to t3.

Unless otherwise stated, a description of an operation of the image sensor during the inactivation period S1 may also be applied to an operation of the image sensor during the second inactivation period S3.

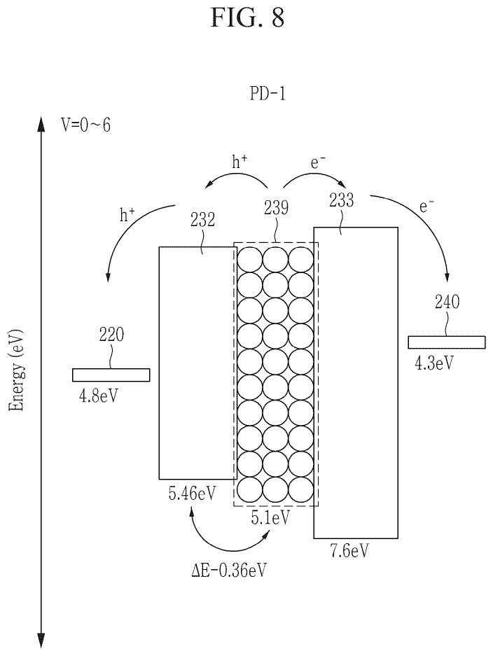

FIG. 8 illustrates a schematic diagram of a bandgap energy diagram of some components included in a pixel according to some example embodiments. In particular FIG. 8 illustrates a bandgap energy diagram of some components included in a photodetector PD-1 of a pixel 200 according to some example embodiments. The pixel 200 illustrated and described with reference to FIG. 8 may be the pixel 200, PX illustrated and described with reference to FIGS. 1-7. The photodetector PD-1 illustrated and described with reference to FIG. 8 may be the photodetector PD illustrated and described with reference to FIGS. 2-7.

In some example embodiments, the photocharge generating layer 239 may be configured to have a first HOMO level and the hole transport layer 232 may be configured to have a second HOMO level that is different from the first HOMO level by a difference value. Referring to FIG. 8, a HOMO (highest occupied molecular orbital) level of the first electrode layer 220 may be 4.8 eV, the HOMO level of the hole transport layer 232 may be 5.46 eV, and the HOMO level of the photocharge generating layer 239 (also referred to herein as a first HOMO level) may be 5.1 eV. The HOMO level of the electron transport layer 233 may be 7.6 eV, and the HOMO level of the second electrode layer 240 may be 4.3 eV. A difference between the HOMO level of the hole transport layer 232 (also referred to herein as a second HOMO level) and the HOMO level of the photocharge generating layer 239 (also referred to herein as a difference value) may be 0.36 eV.

A difference between the HOMO levels of the hole transport layer 232 and the photocharge generating layer 239 (e.g., a magnitude of the difference value) may affect efficient charge transfer in the pixel PX (in FIG. 1). As the difference between the HOMO levels of the hole transport layer 232 and the photocharge generating layer 239 increases, an energy barrier may increase. When the holes 235 (in FIG. 6) are transferred from the photocharge generating layer 239 to the hole transport layer 232, movement of holes may become more difficult as the difference between HOMO levels (e.g., the magnitude of the difference value) increases.

In some example embodiments, if the difference (difference value) between the HOMO levels of the hole transport layer 232 and the photocharge generating layer 239 is greater than or equal to a preset first threshold (also referred to herein as a first threshold value), the photocharge generating layer 239 may enter the deactivation periods S1 and S3 during which a pixel current does not flow because the photocharge generating layer may not sufficiently generate a plurality of electrons or a plurality of holes. In this case, a pixel voltage, which is a voltage of the second electrode layer 240, may be lower than or equal to a second threshold (also referred to herein as a second threshold value). The first threshold may be 0.2 eV and the second threshold may be 0.5 V. In some example embodiments, the first threshold (first threshold value) may be equal to or greater than about 0.2 eV. In some example embodiments, the second threshold (second threshold value) may be equal to or greater than about 0.5 eV.

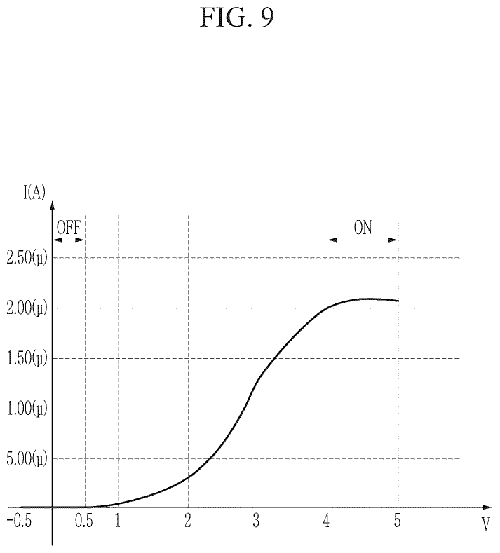

When a pixel voltage that is equal to or higher than the second threshold is output from (e.g., applied to) the second electrode layer 240, the difference between the HOMO level of the hole transport layer 232 and the HOMO level of the photocharge generating layer 239 may be reduced. For example, the image sensor 100 may be configured to cause the difference value between the HOMO level of the photocharge generating layer 239 (the first HOMO level) and the HOMO level of the hole transport layer 232 (the second HOMO level) to decrease based on a pixel voltage that is applied to the second electrode layer 240 being equal to or greater than the second threshold (such pixel voltage equal to or greater than the second threshold value being referred to herein as a first pixel voltage). Accordingly, as a magnitude of the higher pixel voltage than the second threshold increases, an amount (e.g., magnitude) of current flowing from the second electrode layer 240 to the first electrode layer 220 (such current also referred to interchangeably herein as a pixel current, an electrical current, a pixel electrical current, or the like) may increase. Conversely, when a lower pixel voltage than the second threshold value is output from the second electrode layer 240, the difference between the HOMO level of the hole transport layer 232 and the HOMO level of the photocharge generating layer 239 may be increased. For example, the image sensor 100 may be configured to cause the difference value between the HOMO level of the photocharge generating layer 239 (the first HOMO level) and the HOMO level of the hole transport layer 232 (the second HOMO level) to increase based on a pixel voltage that is applied to the second electrode layer 240 being smaller than the second threshold (such pixel voltage smaller than the second threshold value referred to herein as a second pixel voltage). Accordingly, as a magnitude of the higher pixel voltage than the second threshold increases, an amount of current flowing from the second electrode layer 240 to the first electrode layer 220 may increase. This will be described in detail in FIG. 9 below.

FIG. 9 illustrates a graph showing an amount of current (e.g., pixel current) generated based on a voltage applied to a second electrode layer, according to some example embodiments. FIG. 9 illustrates an amount of current generated at the photodetector PD-1 shown in FIG. 8 based on a pixel voltage applied to the second electrode layer 240 of the photodetector PD-1.

Referring to FIGS. 8 and 9, when the pixel voltage of the second electrode layer 240 (e.g., the pixel voltage applied to the second electrode layer 240) is output as −0.5 V to 0.5 V, the electrons 234 (in FIG. 6) and the holes 235 (in FIG. 6) may not be generated in the photocharge generating layer 239. Accordingly, a pixel current may not flow between the first electrode layer 220 and the second electrode layer 240.

When the pixel voltage of the second electrode layer 240 is output as 0.5 V to 4 V, the electrons 234 and the holes 235 may be generated in the photocharge generating layer 239. The electrons 234 may be transferred to the second electrode layer 240 through the electron transport layer 233, and holes 235 may be transferred to the first electrode layer 220 through the hole transport layer 232. A pixel current may flow from the second electrode layer 240 to the first electrode layer 220.

As the pixel voltage output from (e.g., applied to) the second electrode layer 240 increases, an amount (e.g., magnitude) of current flowing from the second electrode layer 240 to the first electrode layer 220 may increase. For example, the amount of the pixel current between the second electrode layer 240 and the first electrode layer 220 may be proportional to a value of the pixel voltage applied to the second electrode layer 240. An amount of current flowing from the second electrode layer 240 to the first electrode layer 220 may increase from 0 (A) to 2.50μ (A). FIG. 9 shows, in an x-axis, the value (e.g., magnitude) of the first pixel voltage applied to the second electrode layer 240, and, in the y-axis, the amount (e.g., magnitude) of the pixel current flowing between the second electrode layer 240 and the first electrode layer 220 (e.g., from the second electrode layer 240 to the first electrode layer 220).

When the pixel voltage of (e.g., applied to) the second electrode layer 240 is output as 4 V to 5 V, the electrons 234 and the holes 235 accumulated in the photocharge generating layer 239 may reach a saturation state. Accordingly, an amount of current flowing from the second electrode layer 240 to the first electrode layer 220 may no longer increase.

Accordingly, the image sensor 100 may be configured to cause a pixel current that is based on the one or more photocharges to flow between the second electrode layer 240 and the first electrode layer 220, and in some example embodiments to cause a floating diffusion node FD as illustrated and described herein and connected to a first end of the photodetector PD-1 such as shown in FIGS. 2-3 to accumulate the one or more photocharges, based on a first pixel voltage (e.g., a pixel voltage that is equal to or greater than a second threshold value, for example at least 0.5 V) being applied to the second electrode layer 240. For example, the photocharge generating layer 239 may be configured to absorb the incident light to generate a plurality of holes and a plurality of electrons based on a pixel voltage that is the first pixel voltage being applied to the second electrode layer, such that the image sensor 100 is further configured to cause the plurality of holes to be transferred to the first electrode layer through the hole transport layer and the plurality of electrons to be transferred to the second electrode layer through the electron transport layer, which may cause the pixel current to flow between the second electrode layer 240 and the first electrode layer 220, based on the photocharge generating layer 239 generating the plurality of holes and the plurality of electrons based on the first pixel voltage being applied to the second electrode layer 240. As a result, the image sensor 100 may be configured to reduce, minimize, or prevent undesired leakage current from being generated at the image sensor 100 and thus to improve shutter efficiency and/or image generation performance of the image sensor 100, based on the difference value between the first and second HOMO levels being equal to or greater than the first threshold value and the image sensor being configured to generate the pixel current based on the photocharge based on the first pixel voltage equal to or greater than the second threshold value being applied to the second electrode layer 240.

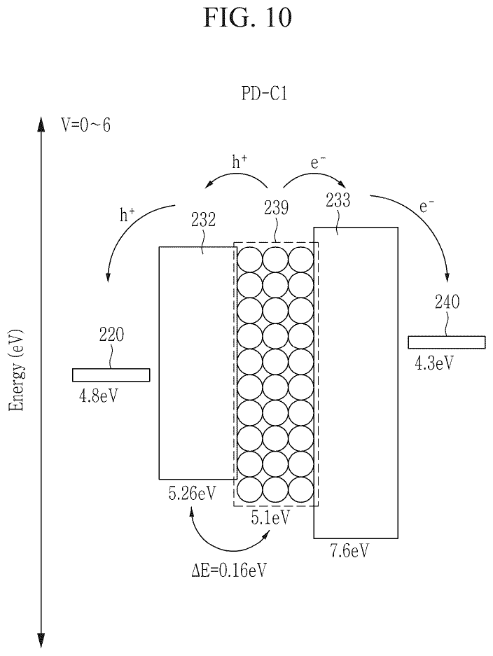

FIG. 10 illustrates a schematic diagram of a bandgap energy diagram of some components included in a pixel according to a comparative embodiment. In particular FIG. 10 illustrates a bandgap energy diagram of some components included in a photodetector PD-C1 of a pixel 200 according to some example embodiments. The pixel 200 illustrated and described with reference to FIG. 10 may be the pixel 200, PX illustrated and described with reference to FIGS. 1-7. The photodetector PD-C1 illustrated and described with reference to FIG. 10 may be the photodetector PD illustrated and described with reference to FIGS. 2-7.

Referring to FIG. 10, a HOMO (highest occupied molecular orbital) level of the first electrode layer 220 may be 4.8 eV, the HOMO level of the hole transport layer 232 (e.g., the second HOMO level) may be 5.26 eV, and the HOMO level of the photocharge generating layer 239 (e.g., the first HOMO level) may be 5.1 eV. The HOMO level of the electron transport layer 233 may be 7.6 eV, and the HOMO level of the second electrode layer 240 may be 4.3 eV. A difference between the HOMO level of the hole transport layer 232 and the HOMO level of the photocharge generating layer 239 (e.g., a difference value) may be 0.16 eV.

A difference between the HOMO levels of the hole transport layer 232 and the photocharge generating layer 239 may affect efficient charge transfer in the pixel PX (in FIG. 1). As the difference between the HOMO levels of the hole transport layer 232 and the photocharge generating layer 239 decreases, an energy barrier may decrease. When holes are transferred from the photocharge generating layer 239 to the hole transport layer 232, movement of holes may be facilitated as the difference between HOMO levels becomes smaller.

In some example embodiments, if the difference between the HOMO levels of the hole transport layer 232 and the photocharge generating layer 239 is less than a preset first threshold (e.g., the first threshold value), a leakage current may be generated by a plurality of electrons or a plurality of holes generated from the photocharge generating layer 239. A pixel voltage, which is a voltage of (e.g., voltage applied to) the second electrode layer 240, may be lower than or equal to a second threshold (e.g., a second threshold value). In this case, the first threshold may be 0.2 eV and the second threshold may be 0.5 V.

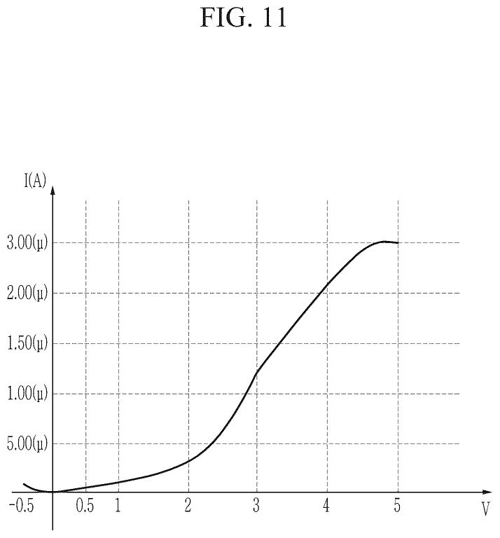

FIG. 11 illustrates a graph showing an amount of current generated based on a voltage applied to a second electrode layer, according to the comparative embodiment. FIG. 11 illustrates an amount of current generated at the photodetector PD-C1 shown in FIG. 10 based on a pixel voltage applied to the second electrode layer 240 of the photodetector PD-C1.

Referring to FIGS. 10 and 11, even when a pixel voltage VP (in FIG. 5) applied to the second electrode layer 240 is output as −0.5 to 0.5 V, a pixel current flowing from the second electrode layer 240 to the first electrode layer 220 may flow. Because the difference between the HOMO levels of the hole transport layer 232 and the photocharge generating layer 239 is 0.16 eV, the holes 235 (in FIG. 6) may leak from the photocharge generating layer 239 to the hole transport layer 232. The electrons 234 (in FIG. 6) may leak from the photocharge generating layer 239 to the electron transport layer 233. Accordingly, a pixel current may flow between the first electrode layer 220 and the second electrode layer 240.

When the pixel voltage of the second electrode layer 240 is output as 0.5 to 5 V, the electrons 234 and the holes 235 may be generated in the photocharge generating layer 239. The electrons 234 may be transferred to the second electrode layer 240 through the electron transport layer 233, and holes 235 may be transferred to the first electrode layer 220 through the hole transport layer 232. A pixel current may flow from the second electrode layer 240 to the first electrode layer 220 based on such transfer. As the pixel voltage of the second electrode layer 240 increases, an amount of current flowing from the second electrode layer 240 to the first electrode layer 220 may increase. An amount of current flowing from the second electrode layer 240 to the first electrode layer 220 may increase from 0 (A) to 3.00μ (A).

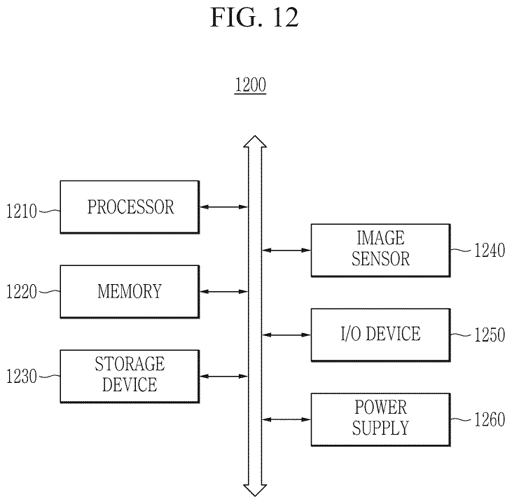

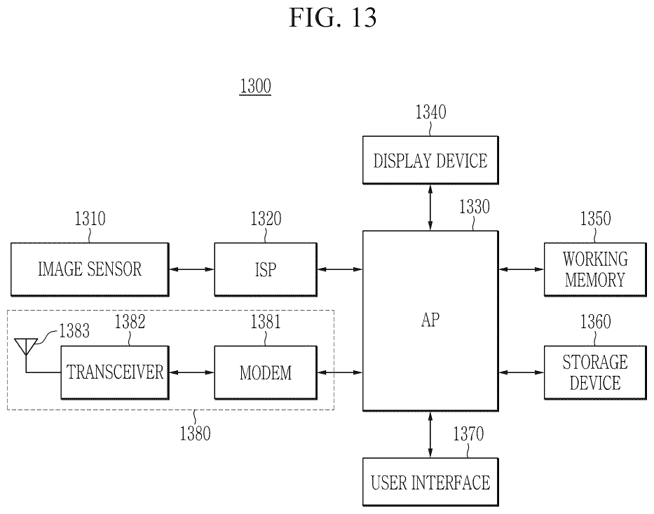

FIG. 12 illustrates a block diagram showing an electronic device according to some example embodiments.

Referring to FIG. 12, the electronic device 1200 may include a processor 1210, a memory 1220, a storage device 1230, an image sensor 1240, an input/output device 1250, and a power supply 1260, and these components may communicate with each other through a bus. Herein, the image sensor 1240 may be the image sensor described with reference to FIGS. 1 through 11. The image sensor 1240 may control the pixel voltage, which is a voltage output from the second electrode layer 240 included in the pixel PX (in FIG. 1).

In some example embodiments, the controller 120 may control the timing controller 130 to adjust operation timings of elements in the pixel array 110 through the row driver 140.

The image sensor 1240 may prevent a pixel current from flowing, or reduce or minimize such flow, by applying the pixel voltage VP (in FIG. 3) to a pixel electrode node (e.g., N1) (in FIG. 3) and/or to the second electrode layer 240 and causing the holes 235 (in FIG. 6) and the electrons 234 (in FIG. 6) generated in the photosensitive layer 230 to have an energy level difference of 0.2 eV between the photosensitive layer 230 (in FIG. 4) and the hole transport layer 232 (in FIG. 4).

The processor 1210 may perform specific calculations or tasks necessary for an operation of the electronic device 1200. The memory 1220 and storage device 1230 may store data necessary for the operation of the electronic device 1200. For example, the processor 1210 may include a microprocessor, a central processing unit (CPU), an application processor (AP), etc., the memory 1220 may include a volatile memory and/or a non-volatile memory, and the storage device 1230 may include a solid state drive (SSD), a hard disk drive (HDD), a CD-ROM, etc. The input/output device 1250 may include an input means such as a keyboard, a keypad, a mouse, etc., and an output means such as a printer, a display, etc. The power supply 1260 may supply an operating voltage necessary for the operation of the electronic device 1200.

FIG. 13 illustrates a block diagram showing an electronic device according to some example embodiments.

Referring to FIG. 13, an electronic device 1300 according to some example embodiments may include an image sensor 1310, an image signal processor (ISP) 1320, an application processor (AP) 1330, a display device 1340, a working memory 1350, a storage device 1360, a user interface 1370, and a wireless transceiver 1380. Herein, the image sensor 1310 and the image signal processor 1320 may be the image sensor and the image signal processor described with reference to FIGS. 1 to 12, respectively.

The image sensor 1310 may generate image data, e.g., raw image data, based on a received optical signal, and may provide the image data to the image signal processor 1320. The image signal processor 1320 may perform image processing to change a data format of image data IDAT, which is digital data regarding an image, and image processing to improve image quality, such as noise removal, brightness adjustment, and sharpness adjustment.

In some example embodiments, the image signal processor 1320 may compensate for a dark current level difference in a light signal received from the image sensor 1310 in real time.

In the present inventive concepts, the image signal processor 1320 is described as being provided separately from the application processor 1330 for better understanding and ease of description, but the example embodiments are not limited thereto. For example, the image signal processor 1320 may not be configured as separate hardware or a combination of hardware and software, but may exist as a sub-component of the application processor 1330.

The application processor 1330 may control an overall operation of the electronic device 1300, and may be provided as a system on chip (SoC) that runs applications, an operating system, etc. The application processor 1330 may control an operation of the image signal processor 1320, and may provide converted image data generated by the image signal processor 1320 to the display device 1340 or store it in the storage device 1360.

The working memory 1350 may store programs and/or data that the application processor 1330 processes or executes. The storage device 1360 may be implemented as a non-volatile memory device such as a NAND flash, a resistive memory, etc., and for example, the storage device 1360 may be provided as a memory card (MMC, eMMC, SD, micro SD), etc. The storage device 1360 may store data and/or programs for execution algorithms that control image processing operations of the image signal processor 1320, and the data and/or programs may be loaded into the working memory 1350 when the image processing operations are performed. For example, the working memory 1350 or the storage device 1360 may include a nonvolatile memory such as a read only memory (ROM), a flash memory, a phase-change RAM (PRAM), a magnetic RAM (MRAM), a resistive RAM (RRAM), a ferroelectric RAM (FRAM), etc., and may include a static RAM) or a dynamic RAM (DRAM) as a volatile memory, but they are not limited to the examples listed above.

The user interface 1370 may be implemented with various devices capable of receiving a user input, such as a keyboard, a curtain key panel, a touch panel, a fingerprint sensor, and a microphone. The user interface 1370 may receive a user input, and may provide a signal corresponding to the received user input to the application processor 1330. The wireless transceiver 1380 may include a modem 1381, a transceiver 1382, and an antenna 1383.

As described herein, any devices, systems, modules, portions, units, controllers, circuits, and/or portions thereof according to any of the example embodiments, and/or any portions thereof (including, without limitation, image sensor 100, pixel array 110, controller 120, timing controller 130, row driver 140, readout circuit 150, ramp signal generator 160, data buffer 170, image signal processor 180, electronic device 1200, processor 1210, memory 1220, storage device 1230, image sensor 1240, input/output device 1250, power supply 1260, electronic device 1300, image sensor 1310, image signal processor 1320, application processor 1330, display device 1340, working memory 1350, storage device 1360, user interface 1370, wireless transceiver 1380, modem 1381, transceiver 1382, antenna 1383, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

While the inventive concepts have been described in connection with what is presently considered to be practical example embodiments, it is to be understood that the inventive concepts are not limited to such example embodiments. On the contrary, the scope of the inventive concepts is intended to cover various modifications and equivalent arrangements included within the spirit and scope of the appended claims.

What is claimed is:

1. An image sensor, comprising:
a first electrode layer;
a second electrode layer;
a photocharge generating layer between the first electrode layer and the second electrode layer, the photocharge generating layer configured to generate a photocharge based on absorbing incident light, the photocharge generating layer configured to have a first highest occupied molecular orbital (HOMO) level;
a hole transport layer between the first electrode layer and the photocharge generating layer, the hole transport layer configured to have a second HOMO level, the second HOMO level different from the first HOMO level by a difference value, the difference value greater than or equal to a first threshold value; and
an electron transport layer between the photocharge generating layer and the second electrode layer,
wherein the image sensor is configured to cause a pixel current based on the photocharge to flow between the second electrode layer and the first electrode layer, based on a first pixel voltage applied to the second electrode layer, the first pixel voltage equal to or greater than a second threshold value.

2. The image sensor of claim 1, wherein
the photocharge generating layer includes a plurality of short-wavelength infrared quantum dots, and the plurality of short-wavelength infrared quantum dots include an indium arsenide (InAs) material.

3. The image sensor of claim 1, wherein
the first threshold value is equal to or greater than 0.2 eV.

4. The image sensor of claim 1, wherein
the second threshold value is equal to or greater than 0.5 V.

5. The image sensor of claim 1, wherein
the image sensor is configured to cause the difference value to decrease based on the first pixel voltage being applied to the second electrode layer.

6. The image sensor of claim 1, wherein
the photocharge generating layer is configured to absorb the incident light to generate a plurality of holes and a plurality of electrons based on the first pixel voltage applied to the second electrode layer, and
the image sensor is configured to cause the plurality of holes to be transferred to the first electrode layer through the hole transport layer and the plurality of electrons to be transferred to the second electrode layer through the electron transport layer.

7. The image sensor of claim 1, wherein
the image sensor is configured to cause the difference value to increase based on a second pixel voltage being applied to the second electrode layer, the second pixel voltage smaller than the second threshold value.

8. An image sensor, comprising:
a first electrode layer on a first surface of a semiconductor substrate;
a photosensitive layer positioned below the first electrode layer, the photosensitive layer including a plurality of short-wavelength infrared quantum dots, the photosensitive layer configured to generate a photocharge based on absorbing incident light;
a second electrode layer positioned at a lower portion of the photosensitive layer;
an insulating layer at a lower portion of the semiconductor substrate, the insulating layer configured to include a floating diffusion region on a second surface of the semiconductor substrate; and
a first metal layer extending from a lower portion of the second electrode layer to the second surface of the semiconductor substrate, the first metal layer configured to transfer the photocharge to the floating diffusion region.

9. The image sensor of claim 8, wherein
the plurality of short-wavelength infrared quantum dots include an indium arsenide (InAs) material.

10. The image sensor of claim 8, wherein
the image sensor is configured to cause the photocharge to be accumulated in the floating diffusion region and the first metal layer.

11. The image sensor of claim 10, further comprising:
a plurality of transistors on the second surface;
a plurality of contacts configured to transfer a plurality of control signals to the plurality of transistors; and
a second metal layer between the second surface and the second electrode layer, the second metal layer configured to block light incident on the first surface from passing through the semiconductor substrate to reach the second surface.

12. The image sensor of claim 11, wherein
the floating diffusion region is spaced apart from the plurality of transistors, and
the image sensor is configured to cause a size of the floating diffusion region to increase in response to accumulation of the photocharge in the floating diffusion region.

13. The image sensor of claim 8, wherein
the photosensitive layer includes:
a photocharge generating layer including the plurality of short-wavelength infrared quantum dots, the photocharge generating layer configured to have a first highest occupied molecular orbital (HOMO) level;
a hole transport layer between the first electrode layer and the photocharge generating layer, the hole transport layer configured to have a second HOMO level, the second HOMO level different from the first HOMO level by a difference value, the difference value greater than or equal to a first threshold value; and
an electron transport layer between the second electrode layer and the photocharge generating layer.

14. The image sensor of claim 13, wherein
the image sensor is configured to cause a plurality of holes generated from the photosensitive layer to be transferred to the hole transport layer and a plurality of electrons generated from the photosensitive layer to be transferred to the electron transport layer, based on a first pixel voltage applied to the second electrode layer, the first pixel voltage equal to or greater than a second threshold value.

15. The image sensor of claim 13, wherein
the first threshold value is equal to or greater than 0.2 eV.

16. The image sensor of claim 14, wherein
the second threshold value is equal to or greater than 0.5 V.

17. The image sensor of claim 13, wherein
the image sensor is configured to cause the difference value to increase based on a second pixel voltage being applied to the second electrode layer, the second pixel voltage smaller than a second threshold value.

18. An image sensor, comprising:
a photodetector including a photosensitive layer, the photosensitive layer including a plurality of short-wavelength infrared quantum dots, the plurality of short-wavelength infrared quantum dots including an indium arsenide material;
a floating diffusion node connected to a first end of the photodetector, the floating diffusion node configured to accumulate a photocharge generated from the photodetector based on a pixel voltage applied to a pixel of the image sensor being equal to or greater than a first threshold value;
a reset transistor connected to the first end of the photodetector and configured to transmit a power supply voltage as a reset signal to the floating diffusion node;
a driving transistor including a driving transistor gate, the image sensor configured to cause a voltage of the floating diffusion node to be applied to the driving transistor gate; and
a selection transistor connected to a first end of the driving transistor, the selection transistor and configured to transmit the voltage of the floating diffusion node as a pixel signal.

19. The image sensor of claim 18, wherein
the photodetector includes
a first electrode layer,
a second electrode layer, the image sensor configured to cause the pixel voltage to be applied to the second electrode layer,
a photocharge generating layer between the first electrode layer and the second electrode layer, the photocharge generating layer configured to generate the photocharge based on absorbing incident light, the photocharge generating layer configured to have a first highest occupied molecular orbital (HOMO) level,
a hole transport layer between the first electrode layer and the photocharge generating layer, the hole transport layer configured to have a second HOMO level, the second HOMO level different from the first HOMO level by a difference value, the difference value greater than or equal to a second threshold value, and
an electron transport layer between the photocharge generating layer and the second electrode layer.

20. The image sensor of claim 19, wherein
the image sensor is configured to cause the difference value to increase based on the pixel voltage being smaller than the first threshold value.
